(19) United States
(12) Patent Application Publication
(10) Pub. No.: US 2026/0363098 A1
(43) Pub. Date: Nov. 12, 2026

(54) THERMALLY ENHANCED LEADFRAME-BASED AREA ARRAY PACKAGE

(71) Applicant: TEXAS INSTRUMENTS INCORPORATED, Dallas, TX (US)

(72) Inventors: Francis Glyde Medina, La Union (PH); Clariz June M. Nayengyeng, Itogon (PH); Mia Katrina Cayabyab, Baguio (PH)

(21) Appl. No.: 19/202,464

(22) Filed: May 8, 2025

(51) Int. Cl. H10W 70/40; H10W 40/22

(52) U.S. Cl. CPC H10W 70/461; H10W 40/228; H10W 70/424; H10W 70/465

(57) ABSTRACT

A semiconductor package comprises a semiconductor die attached to a thermal pad and connected to a lead, the lead including a first surface and an opposing second surface, and the thermal pad including a third surface and an opposing fourth surface; a wire coupled to the semiconductor die and the first surface of the lead; a solder ball coupled to the second surface of the lead; and mold compound in contact with the lead, the thermal pad, and the semiconductor die. A fifth surface of the mold compound is recessed with respect to the second surface of the lead and the fourth surface of the thermal pad, and a first portion of the solder ball and a second portion of the thermal pad are not in contact with the mold compound. In some examples, a plurality of leads is provided in an area array around the thermal pad.

### BACKGROUND

An area array package is a type of surface-mount semiconductor package used for integrated circuits (ICs) in which the electrical connections with a printed circuit board (PCB) are arranged in a grid pattern across the entire surface area of the semiconductor package, rather than just along the edges. These packages allow for a high number of electrical connections to be made in a compact area, which is especially beneficial in electronic devices that require high-density, high-performance components. Such area array packages differ from typical leadframe based packages such as dual inline package (DIP) and quad flat package (QFP) that have electrical connections only along the periphery of the semiconductor package. Ball Grid Array (BGA) package is an example of an area array package, characterized by an array of solder balls arranged in a grid pattern on the underside of the semiconductor package. Land Grid Array (LGA) package is another example of an area array package, which uses landing pads for electrical connectivity with the PCB. LGA packages depend on direct contact between the landing pads and the PCB's matching pads unlike BGA packages, which employ solder balls between the semiconductor package and the PCB.

### SUMMARY

An example semiconductor package includes a semiconductor die attached to a thermal pad and connected to a lead, the lead including a first surface and an opposing second surface, and the thermal pad including a third surface and an opposing fourth surface; a wire coupled to the semiconductor die and the first surface of the lead; a solder ball coupled to the second surface of the lead; and mold compound in contact with the lead, the thermal pad, and the semiconductor die. A fifth surface of the mold compound is recessed with respect to the second surface of the lead and the fourth surface of the thermal pad, and a first portion of the solder ball and a second portion of the thermal pad are not in contact with the mold compound.

Another example semiconductor package comprises a semiconductor die coupled to a first surface of a thermal pad and a plurality of leads arranged in an area array around the thermal pad. The area array includes rows and columns of leads between the thermal pad and any side of the semiconductor package, with any row or any column including at least two leads. The semiconductor package further comprises wires coupled to the semiconductor die and the leads; and a mold compound in contact with the leads, the thermal pad, and the semiconductor die. A third surface of the mold compound is recessed with respect to a second surface of the thermal pad opposite to the first surface.

Yet another example semiconductor package comprises a semiconductor die on a thermal pad; a plurality of leads arranged in an area array around the thermal pad; solder balls coupled to the leads; and a mold compound in contact with the leads, the thermal pad, and the semiconductor die. The area array comprises rows and columns of leads between the thermal pad and any side of the semiconductor package, any row or any column includes more than one lead, adjacent leads in any one row are of different lengths, and the leads are oblique with respect to sides of the semiconductor package.

### BRIEF DESCRIPTION OF THE DRAWINGS

Examples will be readily understood by the following detailed description in conjunction with the accompanying drawings. To facilitate this description, like reference numerals designate like elements. Various aspects are illustrated by way of example, and not by way of limitation, in the figures of the accompanying drawings.

FIGS. 1A-1H are simplified diagrams illustrating various views of an example thermally enhanced leadframe-based area array package and details thereof.

FIG. 2 is a simplified cross-sectional view of details of an example thermally enhanced leadframe-based area array package.

FIG. 3 is a simplified cross-sectional view of details of an example thermally enhanced leadframe-based area array package.

FIGS. 4A-4D are simplified diagrams illustrating various views of an example thermally enhanced leadframe-based area array package and details thereof.

FIGS. 5A and 5B are simplified diagrams illustrating various views of an example thermally enhanced leadframe-based area array package.

FIG. 6 is a simplified cross-sectional view of an example system including a thermally enhanced leadframe-based area array package.

FIG. 7 is a simplified cross-sectional view of another example system including a thermally enhanced leadframe-based area array package.

FIG. 8 is a simplified cross-sectional view of yet another example system including a thermally enhanced leadframe-based area array package.

FIG. 9 is a simplified cross-sectional view of an example operation to make a thermally enhanced leadframe-based area array package.

FIG. 10 is a simplified cross-sectional view of another example operation to make a thermally enhanced leadframe-based area array package.

FIG. 11 is a simplified cross-sectional view of yet another example operation to make a thermally enhanced leadframe-based area array package.

FIG. 12 is a simplified cross-sectional view of yet another example operation to make a thermally enhanced leadframe-based area array package.

FIG. 13 is a simplified cross-sectional view of yet another example operation to make a thermally enhanced leadframe-based area array package.

FIG. 14 is a simplified cross-sectional view of yet another example operation to make a thermally enhanced leadframe-based area array package.

FIG. 15 is a simplified cross-sectional view of yet another example operation to make a thermally enhanced leadframe-based area array package.

FIG. 16 is a simplified cross-sectional view of yet another example operation to make a thermally enhanced leadframe-based area array package.

FIG. 17 is a simplified cross-sectional view of yet another example operation to make a thermally enhanced leadframe-based area array package.

FIG. 18 is a simplified flow diagram of example operations to make a thermally enhanced leadframe-based area array package.

### DETAILED DESCRIPTION

For purposes of illustrating the examples described herein, it is important to understand certain terminology and operations of semiconductor packages. The following foundational information may be viewed as a basis from which various technical aspects described in the present disclosure may be properly explained. Such information is offered for purposes of explanation only and, accordingly, should not be construed in any way to limit the broad scope of the technology presented herein and its potential applications.

In the following detailed description, various aspects of the illustrative implementations may be described using terms commonly employed by those skilled in the art to convey the substance of their work to others skilled in the art.

The term “integrated circuit” means a circuit that is integrated into a monolithic semiconductor or analogous material. A “die” or “semiconductor die” refers to a piece of semiconductor or analogous material (e.g., silicon, gallium nitride, etc.), that contains an IC or other electronic components. The terms “package,” and “semiconductor package” are synonymous, as are the terms “die” and “semiconductor die.”

The terms “circuit” and “circuitry” mean one or more passive and/or active electrical and/or electronic components that are arranged to cooperate with one another to provide a desired function. The terms also refer to analog circuitry, digital circuitry, hard wired circuitry, optical circuitry, programmable circuitry, microcontroller circuitry and/or any other type of physical hardware electrical and/or electronic component.

The term “leadframe” refers to a metal structure comprising a plurality of conductive leads around a central die-attach region, with the leads configured to facilitate electrical coupling between a semiconductor die and a PCB. The leadframe provides mechanical support and electrical interconnections for the semiconductor die. The leads comprise continuous, solid pieces of substantially homogeneous metal (e.g., copper, copper alloy, etc.), optionally including surface coatings of conductive materials (e.g., silver, gold, nickel-palladium-gold, etc.). A lead may be bent, curved etc. but is nevertheless a single continuous piece of metal originating from, or fabricated as part of, the metal leadframe. Note that the leads of the leadframe as used herein are distinct from the conductive pathways of an organic substrate although both provide electrical coupling between the semiconductor die and the PCB. Unlike the lead, the conductive pathway of the organic substrate is not a continuous solid piece of metal but is comprised of separate layers of metal traces and metal vias in layers of organic dielectric material (e.g., bismaleimide triazine (BT) resin, and FR-4 (flame retardant fiber glass epoxy), etc.).

The term “connected” means a direct connection (which may be one or more of a physical, electrically conductive, and/or thermal connection) between the things that are connected, without any intermediary devices, while the term “coupled” means either a direct connection between the things that are connected, or an indirect connection through one or more passive or active intermediary devices.

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

The accompanying drawings are not necessarily drawn to scale. Furthermore, in the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using suitable characterization tools. In such images of real structures, possible processing and/or surface defects could also be visible, e.g., surface roughness, curvature or profile deviation, pit or scratches, not-perfectly straight edges of materials, tapered vias or other openings, and/or inadvertent rounding of corners or variations in thicknesses of different material layers. There may be other defects not listed here but that are common within the field of packaging. All such non-idealized and realistic possibilities are intended to be included in the scope of the various examples described herein.

Note that in the figures, various components are shown as aligned (e.g., at respective interfaces) merely for ease of illustration; in actuality, some or all of them may be misaligned. In addition, there may be other components, such as bond pads, landing pads, metallization, etc. present in the assembly that are not shown in the figures to prevent cluttering. Further, the figures are intended to show relative arrangements of the components within their assemblies, and, in general, such assemblies may include other components that are not illustrated (e.g., various interfacial layers or various other components related to electrical connectivity, or thermal mitigation). Additionally, although some components of the assemblies are illustrated in the figures as being planar rectangles or formed of rectangular solids, this is simply for ease of illustration, and embodiments of these assemblies may be curved, rounded, or otherwise irregularly shaped as dictated by and sometimes inevitable due to the manufacturing processes used to fabricate various components.

In the drawings, a particular number and arrangement of structures and components are presented for illustrative purposes and any desired number or arrangement of such structures and components may be present in various embodiments. Note also that in cross-sectional views, some components shown as touching each other need not touch each other at all; they may be in different planes with intervening material removed.

BGA packages typically use organic substrates to provide electrical connection between the semiconductor die and the PCB. In some such packages, bond pads are typically provided on the periphery of the semiconductor die. The bond pads are electrically coupled to contacts on the top surface of the organic substrate, which are also along the periphery of the semiconductor die. Conductive vias and metal lines are used to reroute from these peripheral pads to an area array on the underside of the organic substrate. The pads on the underside of the package are also typically larger than those on the top, enabling a size and pitch differential from the much smaller semiconductor sized features to the coarser PCB side features. This fanning out is possible due to the multilayered built-up structure of the organic substrate of the BGA package.

However, the organic substrate is not amenable to high-temperature processing or operation because of its high humidity rating. When moisture is absorbed by the organic moisture-absorbing materials of the organic substrate, any subsequent high-temperature soldering process (e.g., solder reflow) can cause the moisture to rapidly vaporize, leading to internal pressure build-up that can potentially cause the package to crack or delaminate. This phenomenon is known as popcorning, and it can damage both the package and the die inside. The organic materials used in BGA packages have a moisture sensitivity level (MSL) rating of MSL3 or higher. MSL is a rating used to describe the susceptibility of semiconductor packages to moisture absorption. MSL ratings are defined in a scale from 1 to 6, where MSL 1 indicates the least sensitivity to moisture and MSL 6 indicates the highest sensitivity. Ceramic packages have low MSL, but they are expensive to source and manufacture. The high MSL rating necessitates that such BGA packages be stored in moisture proof packs, or used in low temperature operations, thereby limiting their utility.

Due to their susceptibility to moisture and heat, traditional BGA packages are not typically used in high temperature settings. In rare circumstances where they are used in high temperature settings, they are connected to thermal pads on the PCB through solder balls, or have a thermal pad dedicated for heat dissipation on the package underside that is connected by thermal vias to the topside of the organic substrate. On the other hand, leadframe based surface mount packages that are used in high-temperature settings may be provided with a dedicated power pad for heat dissipation. In some electronic devices, the power pad is soldered directly to the PCB. In such applications, the power pad has suitable coatings (e.g., nickel-palladium-gold NiPdAu coating) that enable the solder to stick thereto. Power pads are structurally different from thermal pads of BGA packages, for example, as the die is directly attached to the power pad whereas such is not the case with thermal pads in BGA packages.

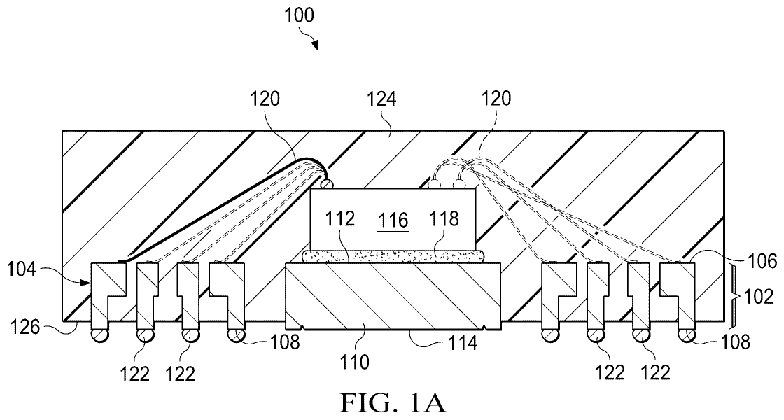

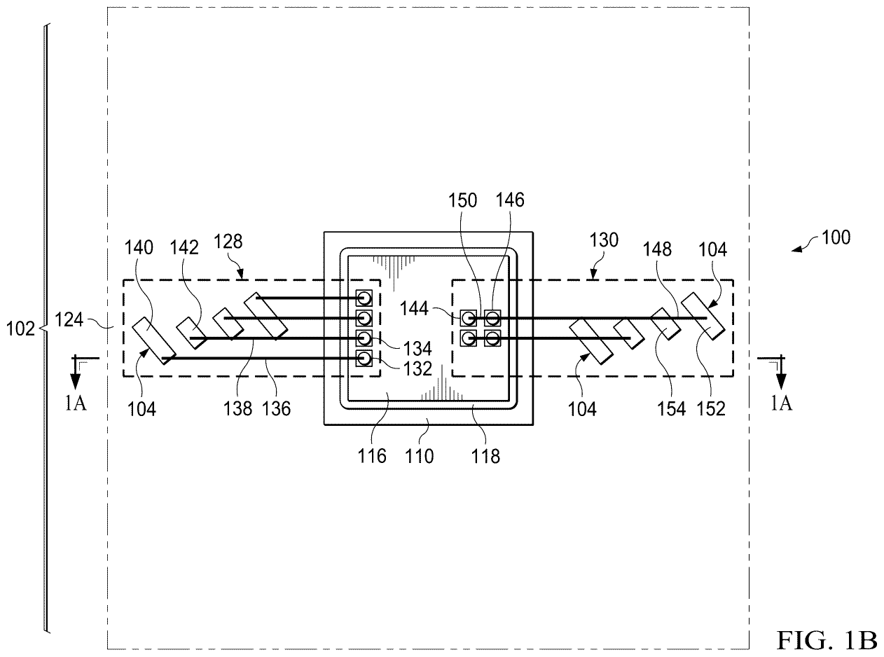

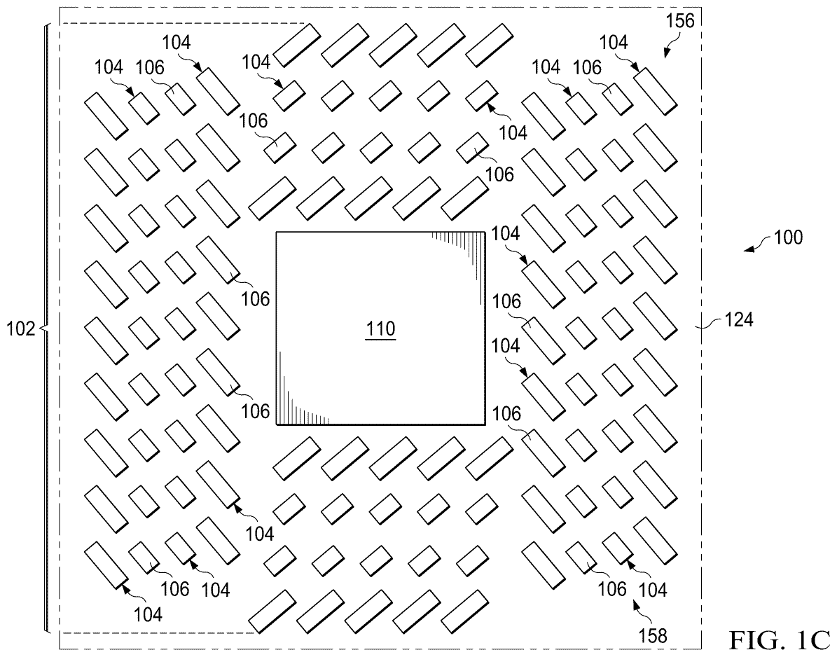

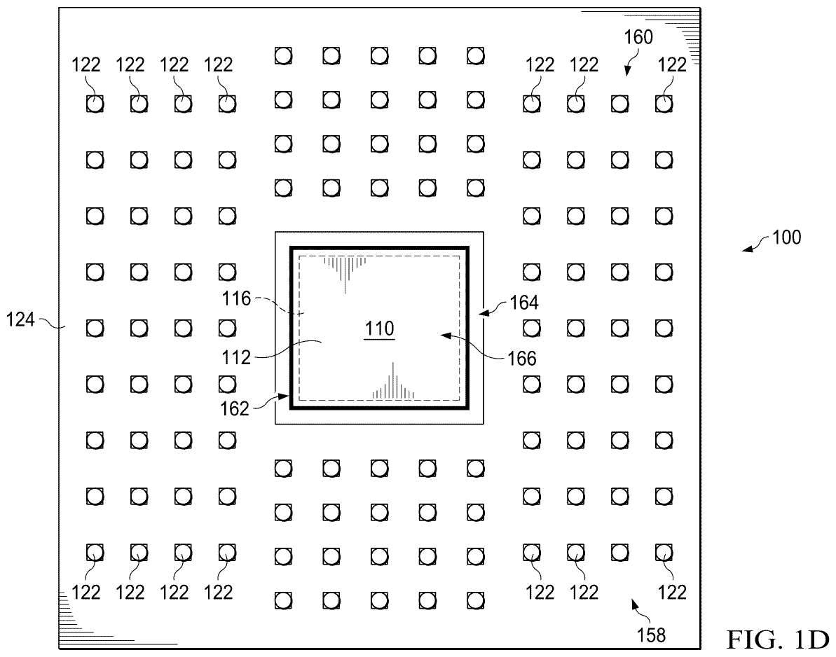

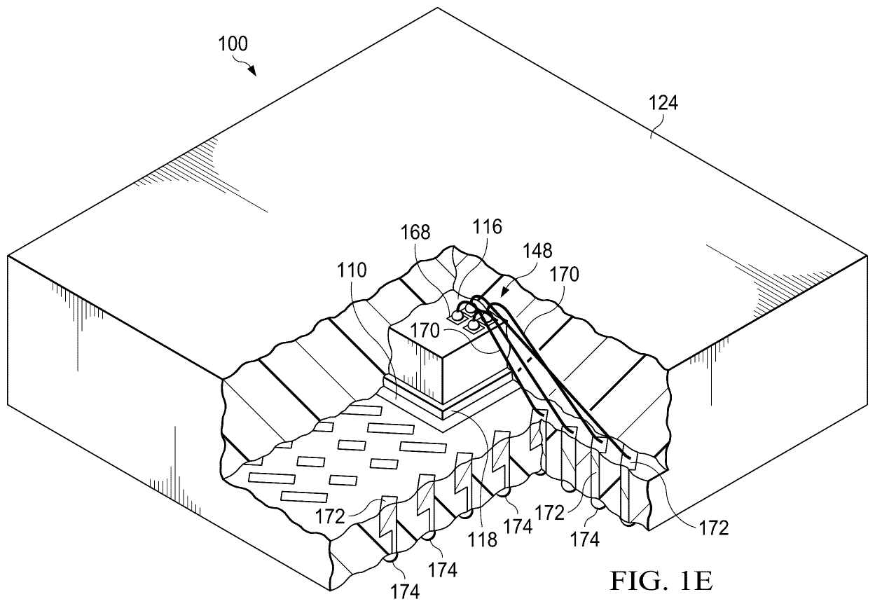

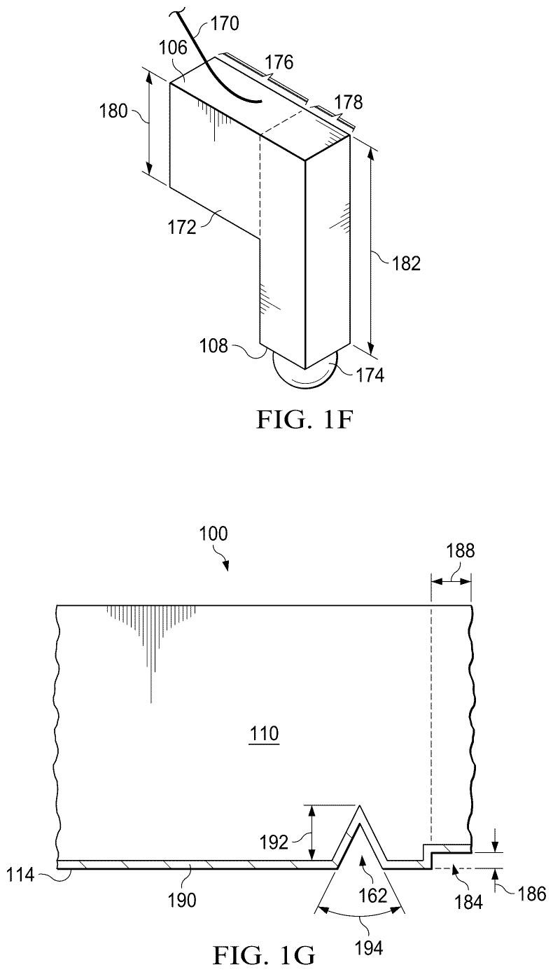

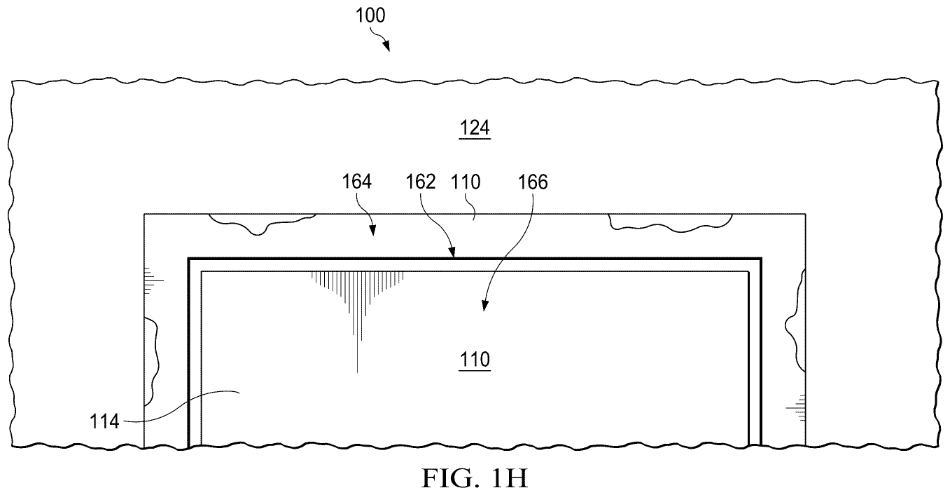

FIGS. 1A-1H are simplified diagrams illustrating various views of an example thermally enhanced leadframe-based area array package. FIG. 1A shows a cross-sectional view of an example semiconductor package 100, comprising a leadframe 102 including leads 104. Leads 104 have a first surface 106 and a second surface 108 opposing first surface 106. Leadframe 102 further includes a thermal pad 110 having a third surface 112 and a fourth surface 114 opposing third surface 112. Semiconductor package 100 further includes a semiconductor die 116 coupled with an adhesive 118 to third surface 112 of thermal pad 110. In some examples, more than one thermal pad 110 may be provided. In some such examples, a corresponding plurality of semiconductor dies may also be provided to form a multi-chip module. In some examples, adhesive 118 may be a thermal adhesive, such as to facilitate efficient heat transfer between semiconductor die 116 and leadframe 102.

Wires 120 (also referred to herein as bond wires) are coupled to semiconductor die 116 and first surface 106 of leads 104 with wirebonds. Note that in the figure some wires are shown in continuous line and others are shown in dotted lines; such a representation is merely to indicate their relative planes. The wires shown in dotted lines may be in a cross-sectional plane behind (or in front of) the wires shown in continuous line. Solder balls 122 are coupled to second surface 108 of leads 104. In various examples, solder balls 122 are capable of being attached (e.g., soldered) to a printed circuit board. A mold compound 124 encloses semiconductor package 100. In various examples, mold compound 124 is in contact with leads 104, thermal pad 110, and semiconductor die 116. A fifth surface 126 of mold compound 124 is recessed with respect to second surface 108 and fourth surface 114 so that solder balls 122 and thermal pad 110 (or portions thereof) are exposed through mold compound 124. In some examples, portions of second surface 108 may also be exposed through mold compound 124. Note that mold compound 124 may not be in contact with such exposed portions of solder ball 122, leads 104, and thermal pad 110.

FIG. 1B is a simplified diagram illustrating a top view of semiconductor package 100 with portions of leadframe 102 exposed through mold compound 124. Two different wire layouts 128 and 130 are shown merely for explanation. In some examples, wire layout 128 may be provided; in other examples, wire layout 130 may be provided; in yet other examples, both wire layouts 128 and 130 may be provided. Note that various other features are shown but not labeled to prevent clutter.

In wire layout 128, bond pads 132 and 134 may be provided in a single row on semiconductor die 116. Wires 136 and 138 couple bond pads 132 and 134 with respective leads 140 and 142. Leads 140 and 142 may be arranged so that wires 136 and 138 may be formed with bond pads 132 and 134 within manufacturing tolerances. In such an arrangement, wires 148 and 150 may lie on separate cross-sectional planes so that they are distinctly visible in the plan view. In wire layout 130, bond pads 144 and 146 may be provided in two rows on semiconductor die 116. Wires 148 and 150 couple bond pads 144 and 146 with respective leads 152 and 154. Leads 152 and 154 may be arranged so that wires 148 and 150 may be formed with bond pads 144 and 146 within manufacturing tolerances. In such an arrangement, wires 148 and 150 may align with each other so that they coincide and are not separately visible in the plan view.

Leads 104 are shown as rectangles arranged obliquely to the edges of semiconductor package 100. Some leads 104, for example, leads 140 and 152 are shown longer than other leads 104, for example, leads 142 and 154. Such shapes and arrangements are shown merely for illustrative purposes. Leads 104 may be shaped and arranged in any suitable arrangement that is feasible, practical, or otherwise suitable to enable forming wires 120 with semiconductor die 116.

Note that other layouts with more than two rows of bond pads and other arrangement of leads are also encompassed within the broad scope of the examples contemplated herein. Note also that only a portion of leadframe 102 is shown as visible in the drawing merely for ease of illustration and explanation. In many examples, bond pads may be distributed around the periphery of semiconductor die 116 and leads may be arranged in an area array around thermal pad 110.

FIG. 1C is a simplified diagram illustrating a top view of semiconductor package 100 with portions of mold compound 124 removed so that first surface 106 of leads 104 is exposed therethrough. Leads 104 are shaped and arranged according to a pattern 156 (e.g., arrangement, layout, scheme, design, formation, configuration, etc.) covering a substantial portion of a region 158 around thermal pad 110. In some examples, pattern 156 comprises an area array of rows and columns of leads 104 between thermal pad 110 and any side of semiconductor package 100. Any row or column may include at least two leads 104. In some examples, as shown, at least two adjacent leads 104 may be of different lengths. Further, according to pattern 156, leads 104 are oblique with respect to thermal pad 110 or sides of semiconductor package 100 (e.g., each lead may be at an oblique angle with respect to the periphery of semiconductor package 100). Some leads 104 may be longer, shorter, wider, narrower, or otherwise larger or smaller than some other leads 104 in some examples. In other examples, leads 104 may be substantially similar in size and shape. Pattern 156 may be based on efficient and compact arrangement of wires compatible with wirebonding manufacturing tolerances; size and pitch of bond pads; manufacturing considerations of leadframe 102 according to particular needs; and other factors beyond the scope of the disclosure. Note that pattern 156 is different from the arrangement of leads in typical leadframe based packages where the leads do not cover a substantial portion of region 158 but rather radiate out from the periphery of the semiconductor die towards the edges of the semiconductor package.

FIG. 1D is a simplified diagram illustrating a bottom view (i.e., underside) of semiconductor package 100 according to some examples. In the example shown, second surface 108 of leads 104 is covered by solder balls 122 and is therefore not visible. Solder balls 122 may be arranged in a pattern 160 covering a substantial portion of region 158 around thermal pad 110. Leads 104 (not shown) may be shaped so that second surface 108 also corresponds to pattern 160. In other words, leads 104 may have a first shape along first surface 106 and a second shape along second surface 108. In various examples, pattern 160 may be selected based on desired solder ball density, pitch and ball size according to particular needs; and other factors beyond the scope of the disclosure.

In various examples, thermal pad 110 may include a groove 162 proximate to a periphery of thermal pad 110, dividing fourth surface 114 of thermal pad 110 into an outer portion 164 (e.g., comprising a periphery of thermal pad 110) and an inner portion 166 (e.g., comprising a center of thermal pad 110). In such examples, groove 162 may function as a stop preventing mold compound 124 from contacting inner portion 166 during the manufacture of semiconductor package 100. For example, mold compound 124 may not extend beyond groove 162 towards a center of thermal pad 110. In the example shown, mold compound 124 may function as a solder mask preventing solder balls 122 from contacting each other. In some other examples, a layer of solder mask may be provided for the same purpose. In yet other examples, portions of second surface 108 of leads 104 may be visible in the bottom view.

FIG. 1E is a simplified diagram illustrating a perspective view of semiconductor package 100 with cutout showing internal details according to some examples. An example set of features is labeled with particularity for ease of explanation. Bond pad 168 is connected by a wire 170 to a lead 172. Lead 172 may have a sufficient surface area on first surface 106 to accommodate the wedge bond (or other suitable type of bond) created during the wirebonding process. Lead 172 may be coupled on second surface 108 to a solder ball 174. The surface area of lead 172 on second surface 108 may be different from the surface area on first surface 106.

Lead 172 is shown in greater detail in perspective in FIG. 1F. First surface 106 of lead 172, proximate to semiconductor die 116, may have a first surface area and second surface 108 of lead 172, opposite to first surface 106 may have a second surface area. The first surface area may be larger than the second surface area in some examples (as shown). In some other examples (not shown), the first surface area may be substantially similar to the second surface area. Leads 104 with relatively different first surface areas and second surface areas may be present in a single instance of semiconductor package 100. In some examples, lead 172 may comprise a first portion 176 and a second portion 178. First portion 176 is proximate to wire 170 and in contact therewith. Second portion 178 is proximate to solder ball 174 and in contact therewith. First portion 176 may have a first thickness 180; second portion 178 may have a second thickness 182. In the example shown, first thickness 180 is less than second thickness 182. In some other examples, first thickness 180 may be substantially the same as second thickness 182. In some examples, second portion 178 may be the same as first portion 176 (e.g., solder ball 174 may be directly aligned with the bonded end of wire 170).

FIG. 1G is a simplified cross-sectional view of a portion of thermal pad 110 in semiconductor package 100 according to an example. Thermal pad 110 may include a recess 184 along a periphery. Recess 184 may have a depth 186 and width 188. In some examples, depth 186 may be less than 25 micrometers; and width 188 may be approximately 130 micrometers. A conductive coating 190 is in contact with fourth surface 114 of thermal pad 110. In some examples, conductive coating 190 may comprise a nickel-palladium-gold alloy. In other examples, conductive coating 190 may comprise gold only. In other examples, conductive coating 190 may comprise other metal alloys that facilitate solder bonding. In yet other examples, conductive coating 190 may be absent. In various examples, the thickness of conductive coating 190 may be less than depth 186; for example, conductive coating 190 may have a thickness of approximately 5 micrometers and depth 186 may be approximately 20 micrometers. In some examples, the thickness of conductive coating 190 may vary between 3 micrometers and 10 micrometers. Groove 162 may have a groove depth 192 and a groove angle 194. In some examples, groove depth 192 is approximately 25 micrometers and groove angle 194 is 60°.

FIG. 1H is a simplified bottom view (underside) of semiconductor package 100 showing details around thermal pad 110. During manufacturing mold compound 124 may be added in liquid or semi-liquid form. Groove 162 along the periphery of thermal pad 110 may prevent mold compound 124 in liquid form from seeping (e.g., flowing, extending, extruding, leaking, etc.) into inner portion 166 of fourth surface 114. Mold compound 124 may be in contact with some parts of outer portion 164 of fourth surface 114 of thermal pad 110, leaving other parts exposed.

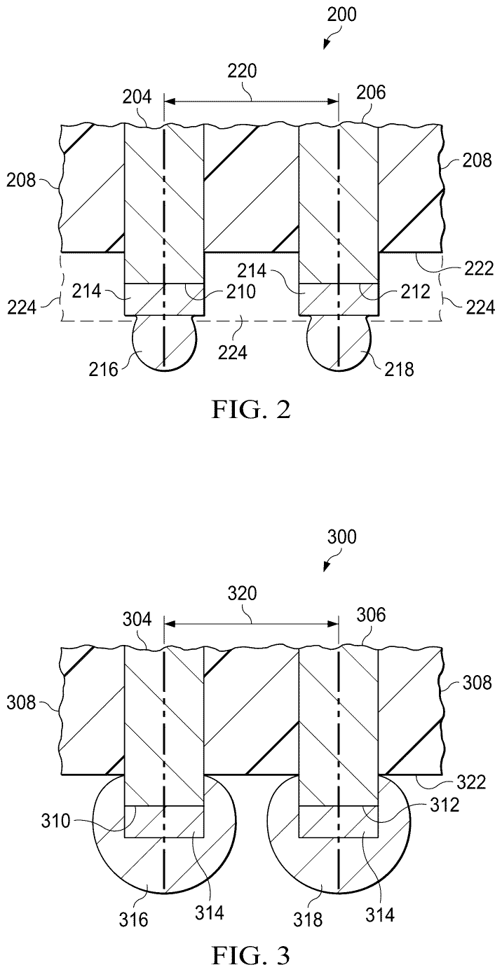

FIG. 2 is a simplified cross-sectional view of details of an example semiconductor package 200. Semiconductor package 200 is substantially similar to semiconductor package 100 described in reference to FIG. 1A. Leads 204 and 206 may be substantially similar to lead 104 described in reference to FIG. 1A. Mold compound 208, substantially similar to mold compound 124 is in contact with leads 204 and 206. Surfaces 210 and 212 of respective leads 204 and 206 may be coated with a conductive coating 214. In various examples, conductive coating 214 may be substantially similar to conductive coating 190 on thermal pad 110 as described in reference to FIG. 1G.

Leads 204 and 206 may be coupled to respective solder balls 216 and 218, having a pitch 220 therebetween. As described in reference to FIG. 1A, a surface 222 of mold compound 208 may be recessed with respect to surfaces 210 and 212 of leads 204 and 206, respectively. Depending on the size of solder balls 216 and 218 and pitch 220, solder balls 216 and 218 may be contained within the perimeter of respective leads 204 and 206. In some examples an additional layer of solder mask 224 may be in contact with surface 222 of mold compound 208 and lateral sides of leads 204 and 206. In some such examples, leads 204 and 206 may be exposed as solder mask defined pads such that solder balls 216 and 218 are constrained to be within the boundaries of solder mask 224.

FIG. 3 is a simplified cross-sectional view of details of an example semiconductor package 300. Semiconductor package 300 is substantially similar to semiconductor package 100 described in reference to FIG. 1A. Leads 304 and 306 may be substantially similar to lead 104 described in reference to FIG. 1A. Mold compound 308, substantially similar to mold compound 124 is in contact with leads 304 and 306. Surfaces 310 and 312 of respective leads 304 and 306 may be coated with a conductive coating 314. In various examples, conductive coating 314 may be substantially similar to conductive coating 190 on thermal pad 110 as described in reference to FIG. 1G.

Leads 304 and 306 may be coupled to respective solder balls 316 and 318, having a pitch 320 therebetween. As described in reference to FIG. 1A, a surface 322 of mold compound 308 may be recessed with respect to surfaces 310 and 312 of leads 304 and 306, respectively. Depending on the size of solder balls 316 and 318 and pitch 320, solder balls 216 and 218 may wet the lateral sides of leads 304 and 206, respectively. In some such examples, leads 304 and 306 may present as non-solder mask defined (NSMD) pads. Note that the underside of package 100 shown in FIG. 1D may comprise solder balls 122 in a configuration as explained in reference to FIG. 3, so that no portion of leads are visible to the naked eye.

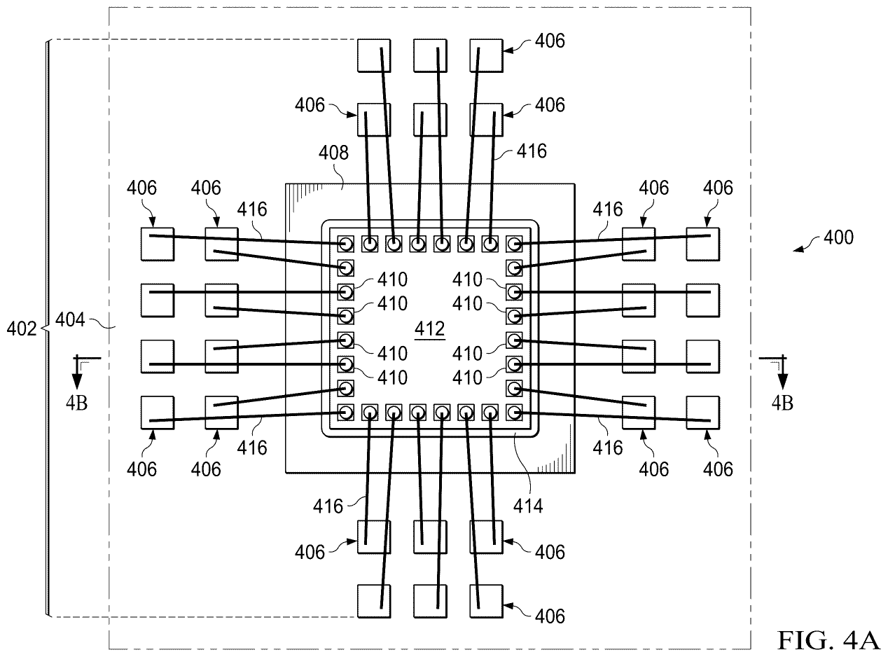

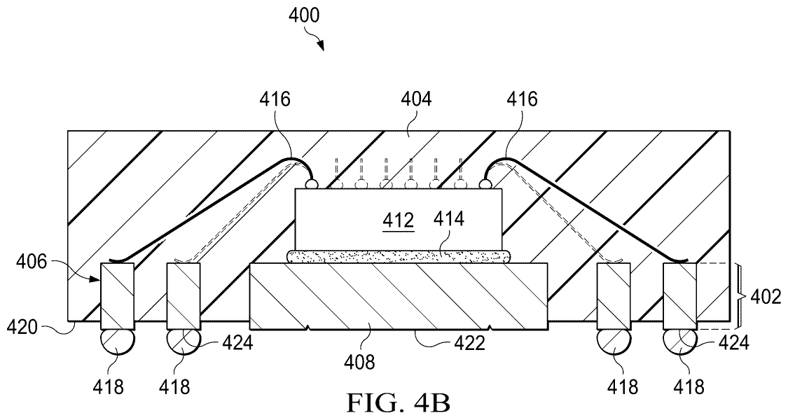

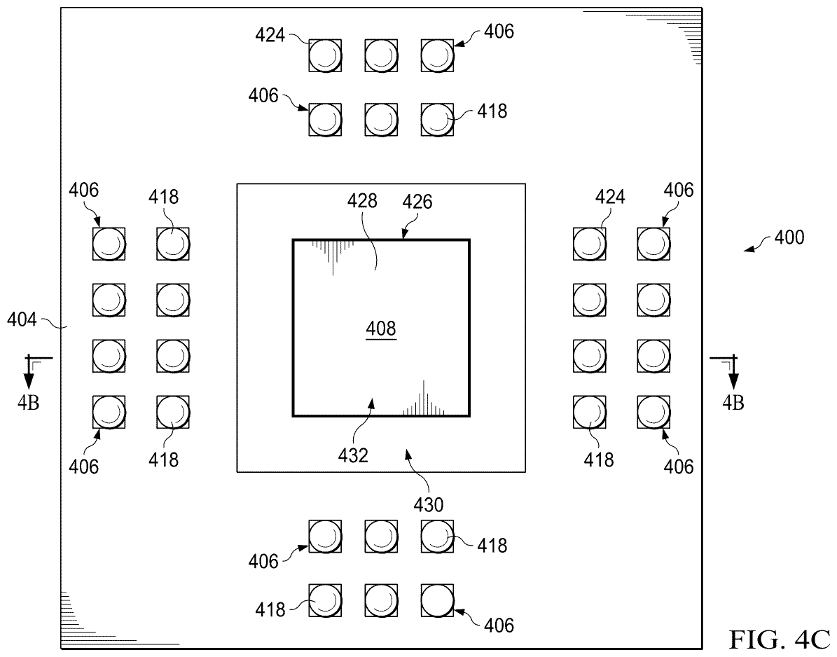

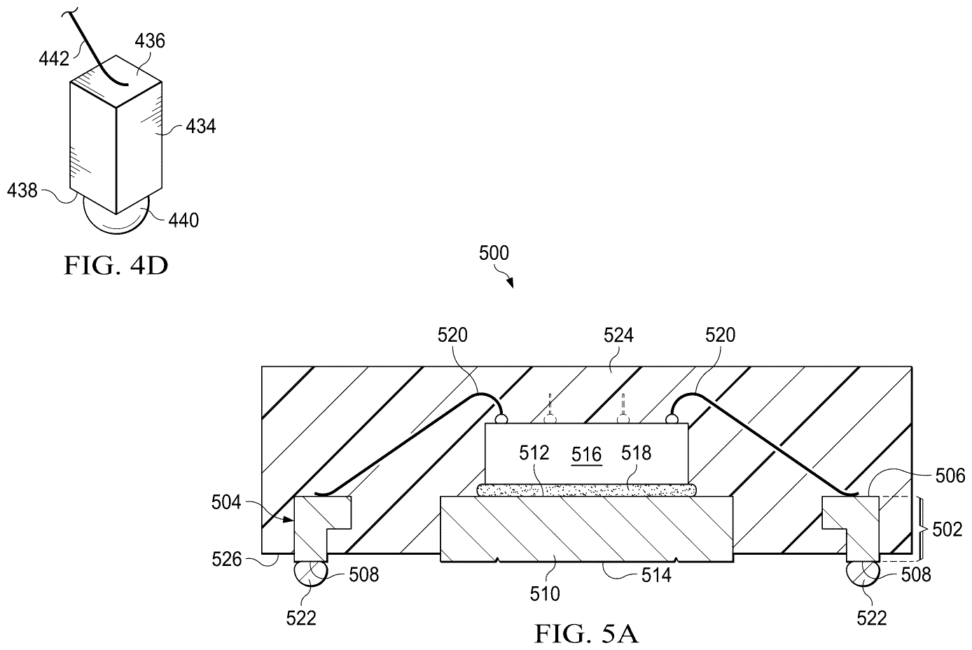

FIGS. 4A-4D are simplified diagrams illustrating another example semiconductor package 400 and details thereof. FIG. 4A is a simplified diagram illustrating a top view of semiconductor package 400 with portions of a leadframe 402 exposed through a mold compound 404. Leadframe 402 comprises leads 406 and a thermal pad 408. Leads 406 are shown as rectangles arranged in an area array around thermal pad 408. Such is merely for illustrative purposes. Leads 406 may be arranged in any suitable area array arrangement that is feasible, practical, or otherwise suitable to enable electrical connectivity with semiconductor die 412. Bond pads 410 may be provided in a single row along a periphery of a semiconductor die 412. Semiconductor die 412 may be attached to thermal pad 408 with an adhesive 414. Bond pads 410 may be coupled by wires 416 to leads 406. In some examples, leads 406 may be arranged so that wirebonding is feasible with bond pads 410 within manufacturing tolerances. Note that other layouts, for example, with two or more rows of bond pads 410 and other arrangement of leads 406 are also encompassed within the broad scope of the examples contemplated herein. Note also that only a portion of leadframe 102 is shown as visible in the drawing merely for ease of illustration and explanation.

FIG. 4B is a simplified cross-sectional view of semiconductor package 400. In the example shown, leadframe 402 may have a uniform thickness throughout. Wires shown as dotted lines are shown merely for ease of explanation; they are not in the plane of cross-section; they may be behind or in front of the plane. Leads 406 may be coupled to solder balls 418 on a side opposite to wires 416. In various examples, surface 420 of mold compound 404 may be recessed from respective surfaces 422 and 424 of thermal pad 408 and leads 406 as described in reference to FIG. 1A. Note that although solder balls 418 are shown as being confined within the boundaries of leads 406, similar to the configuration of FIG. 2, such is merely for illustrative purposes. In some examples, solder balls 418 may be disposed along the lateral sides of leads 406, similar to the structure of FIG. 3 so that surface 424 of leads 406 is not visible.

FIG. 4C is a simplified bottom view of the underside of semiconductor package 400. In the example shown, portions of surface 424 of leads 406 are visible around solder balls 418. In some such examples, solder balls 418 may be coupled to leads 406 according to the structure shown and described in FIG. 2. In various examples, thermal pad 408 may include a groove 426 around its periphery, dividing surface 428 of thermal pad 408 into an outer portion 430 and an inner portion 432. In such examples, groove 426 may function as a stop preventing mold compound 404 from contacting inner portion 432 during the manufacture of semiconductor package 400.

FIG. 4D is a simplified perspective view of an example lead 434 of semiconductor package 400. A first surface 436 of lead 434, proximate to semiconductor die 412, may have a first surface area and a second surface 438 of lead 434, opposite to first surface 436 may have a second surface area. The first surface area may be substantially similar to the second surface area in some examples (as shown). In some other examples (not shown), the first surface area may be substantially different from the second surface area. Leads 406 with relatively different first surface areas and second surface areas may be present in a single example of semiconductor package 100. Lead 434 may have a uniform thickness and cross-section between first surface 436 and second surface 438. In some such examples, solder ball 440, coupled to second surface 438 may be aligned with a contact area of wire 442 on first surface 436.

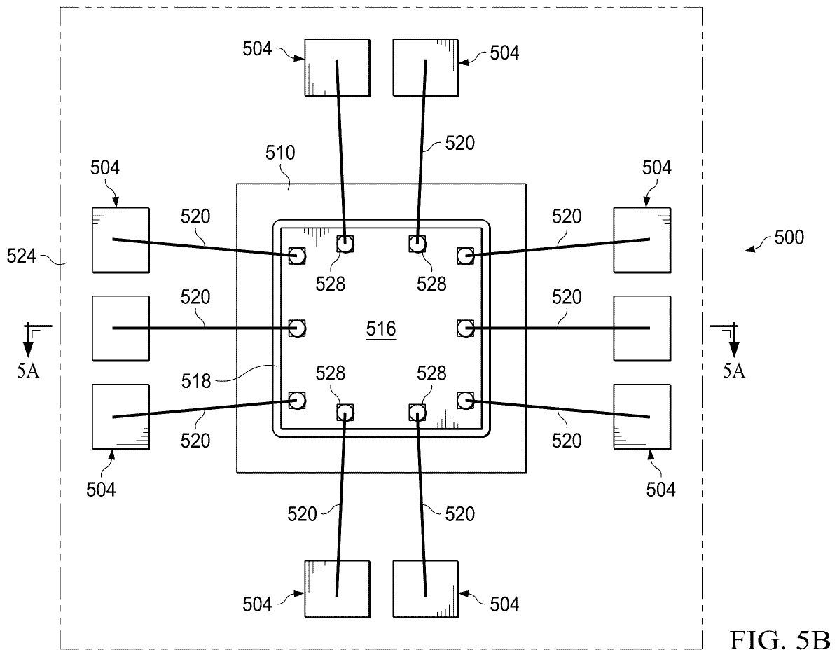

FIGS. 5A-5B are simplified views of an example semiconductor package 500 and details thereof. FIG. 5A shows a cross-sectional view of an example semiconductor package 100, comprising a leadframe 502 including leads 504. Leads 104 have a first surface 506 and a second surface 508 opposite to first surface 506. In the example shown, first surface 506 may have a larger area than second surface 508. In some examples (as shown), leads 406 may have non-uniform thickness between first surface 506 and second surface 508, for example, as described in reference to FIG. 1F. Leadframe 102 further includes a thermal pad 510 having a third surface 512 and a fourth surface 514 opposite to third surface 512. Semiconductor package 100 further includes a semiconductor die 516 coupled with an adhesive 518 to third surface 512 of thermal pad 510. In some examples, adhesive 518 may be a thermal adhesive, such as to facilitate efficient heat transfer between semiconductor die 516 and leadframe 502.

Wires 520 are coupled to semiconductor die 516 and first surface 506 of leads 406 with wirebonds. Solder balls 522 are coupled to second surface 508 of leads 504. A mold compound 524 encloses semiconductor package 500. In various examples, mold compound 524 is in contact with leads 504, thermal pad 510, and semiconductor die 516. A fifth surface 526 of mold compound 524 is recessed with respect to second surface 508 and fourth surface 514 so that solder balls 522 and thermal pad 510 (or portions thereof) are exposed through mold compound 524 on an underside of semiconductor package 500. In some examples, portions of second surface 508 of leads 504 may be exposed through mold compound 524. Note that mold compound 524 may not be in contact with such exposed portions of solder balls 522, leads 406, and thermal pad 510.

FIG. 5B is a simplified diagram illustrating a top view of semiconductor package 500 with portions of leadframe 502 exposed through mold compound 524. Wires 520 may couple leads 504 with corresponding bond pads 528 on semiconductor die 516. Leads 504 may be arranged around a periphery of semiconductor die 516 in any suitable arrangement that is feasible or otherwise practical to enable electrical connectivity therewith. In the example shown, leads 504 are shown as rectangular. In other examples, other shapes (e.g., flared, tapered, etc.) may be used without departing from the scope of the disclosure. Note that alternate layouts with more than one row of bond pads and other arrangement of leads are also encompassed within the broad scope of the examples contemplated herein. In some such examples, semiconductor package 500 may be substantially similar to a QFN, except that solder balls may be used to couple to a PCB instead of other types of interconnections.

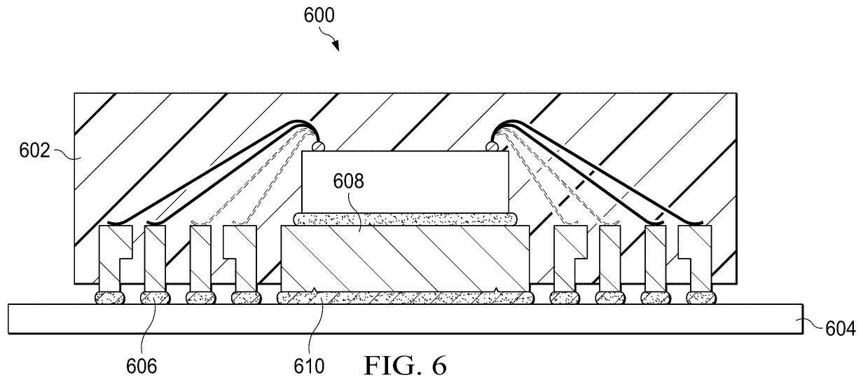

FIG. 6 is a simplified diagram showing a cross-sectional view of a system 600 including a semiconductor package 602. Semiconductor package 602 is substantially similar to semiconductor package 100 as described in reference to FIG. 1. Semiconductor package 602 is connected to a PCB 604 by solder balls 606. A thermal pad 608 in semiconductor package 602 is coupled by thermal paste 610 to PCB 604. Thermal pad 608 is substantially similar to thermal pad 110 as described in reference to FIG. 1. Thermal paste 610 facilitates heat dissipation from semiconductor package 602 to PCB 604. In some examples, thermal paste 610 may comprise solder. In some other examples, thermal paste 610 may comprise silver-based thermal paste, ceramic-based thermal paste, carbon based thermal paste and other such materials that facilitate heat transfer.

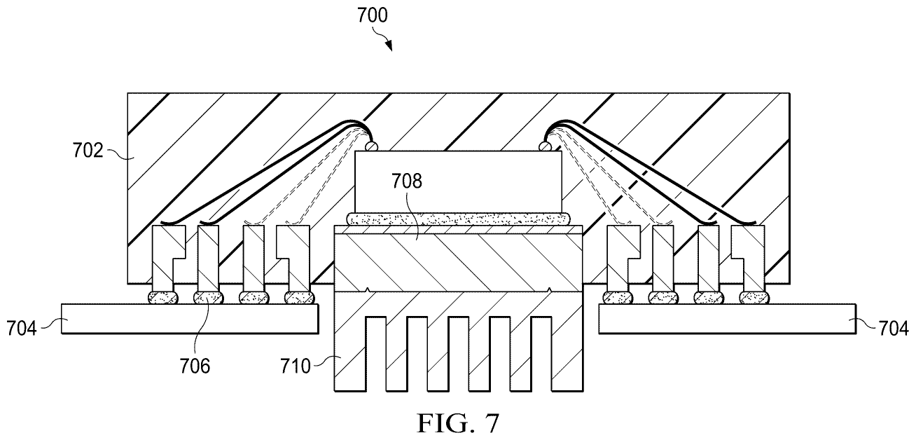

FIG. 7 is a simplified diagram showing a cross-sectional view of a system 700 including a semiconductor package 702. Semiconductor package 702 is substantially similar to semiconductor package 100 as described in reference to FIG. 1. Semiconductor package 702 is connected to a PCB 704 by solder balls 706. A thermal pad 708 in semiconductor package 702 is coupled to a heat sink 710. Thermal pad 708 is substantially similar to thermal pad 110 as described in reference to FIG. 1. PCB 704 may include a hole to accommodate heat sink 710 therethrough. Heat sink 710 facilitates heat dissipation from semiconductor package 702.

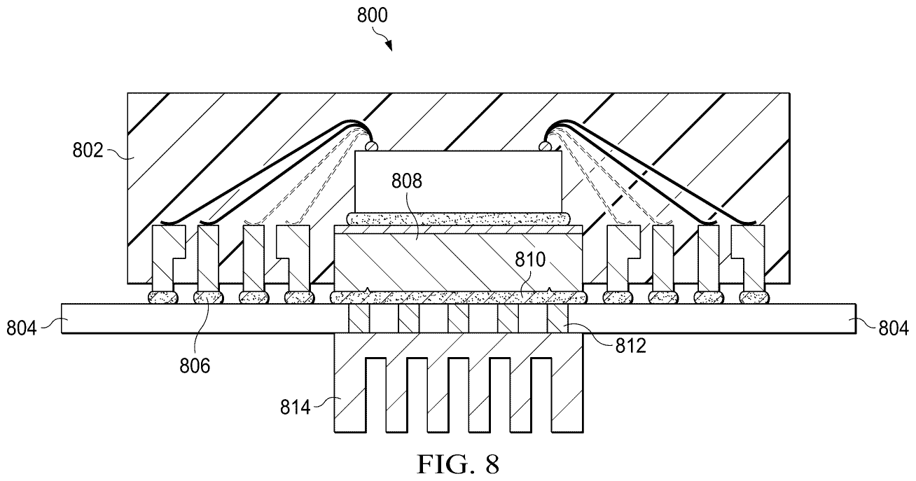

FIG. 8 is a simplified diagram showing a cross-sectional view of a system 800 including a semiconductor package 802. Semiconductor package 802 is substantially similar to semiconductor package 100 as described in reference to FIG. 1. Semiconductor package 802 is connected to a PCB 804 by solder balls 806. A thermal pad 808 in semiconductor package 802 is coupled by thermal paste 810 to PCB 804. Thermal pad 808 is substantially similar to thermal pad 110 as described in reference to FIG. 1. Thermal paste 810 facilitates heat dissipation from semiconductor package 802 through thermal vias 812 in PCB 804 to a heat sink 814 coupled on a side of PCB 804 opposite to semiconductor package 802. In some examples, thermal paste 810 may comprise solder. In some other examples, thermal paste 810 may comprise silver-based thermal paste, ceramic-based thermal paste, carbon based thermal paste and other such materials that facilitate heat transfer.

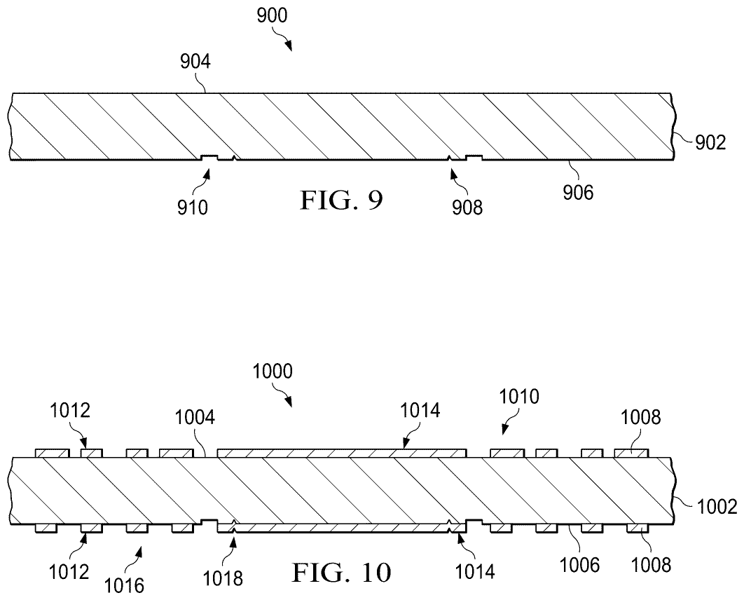

FIGS. 9-16 show simplified cross-sectional views of various stages of example manufacturing operations to make a thermally enhanced leadframe-based area array package such as semiconductor package 100 described in FIG. 1. As shown in FIG. 9, at operation 900, a copper plate 902 may be provided. Copper plate 902 may have a first surface 904 and a second surface 906. Copper plate 902 may have a thickness corresponding to the desired thickness of leadframe 102 of semiconductor package 100 as described in reference to FIG. 1. A groove 908 and recess 910 may be formed in second surface 906 in a shape substantially similar to groove 162 and recess 184 respectively described in reference to FIG. 1G. Note that the figure is not to scale so that these features are shown in exaggerated dimensions.

As shown in FIG. 10, at operation 1000, a copper plate 1002 may be provided, similar to copper plate 902. Copper plate 1002 may have a first surface 1004 and a second surface 1006. During operation 1000, a conductive coating 1008 may be coated on first surface 1004 according to a pattern 1010. Pattern 1010 may include shapes 1012 corresponding to leads and another shape 1014 corresponding to a thermal pad. In some examples, shapes 1012 of pattern 1010 may correspond to pattern 156 as described in reference to FIG. 1C. Conductive coating 1008 may be coated on second surface 1006 according to a pattern 1016. Pattern 1016 may include shapes 1012 corresponding to leads and another shape 1014 corresponding to the thermal pad. In some examples, shapes 1012 of pattern 1016 may correspond to pattern 160 as described in reference to FIG. 1D. A groove 1018 may be formed in shape 1014 corresponding to the thermal pad. Note that additional features such as the recess similar to recess 910 as described in FIG. 9 may be provided but are not shown so as not to clutter the drawing. In various examples, conductive coating 1008 on second surface 1006 may conform to such groove and recess suitably. Conductive coating 1008 may comprise a material that is resistant to etching of copper. In some examples, conductive coating 1008 may comprise an alloy of nickel, palladium and gold.

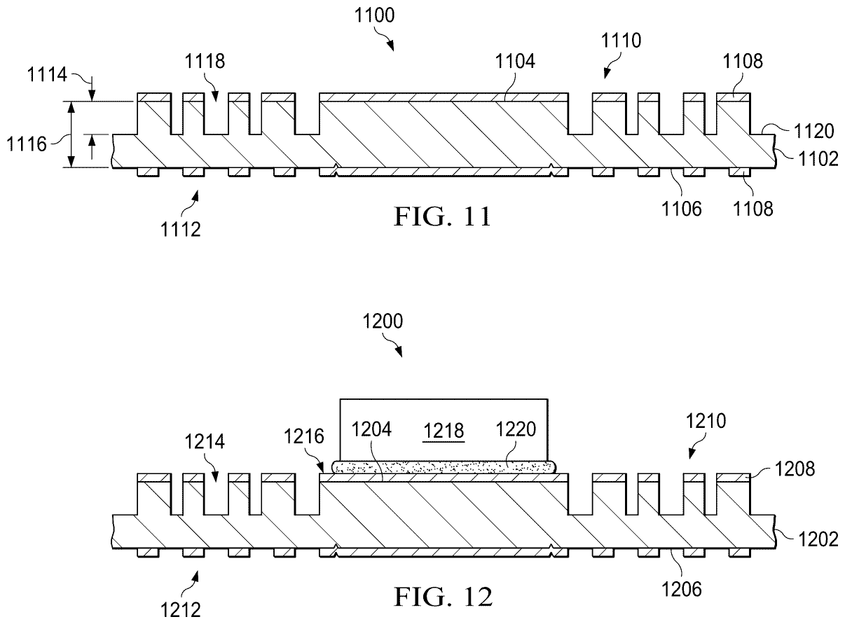

As shown in FIG. 11, at operation 1100, a copper plate 1102 may be provided, similar to copper plate 1002. Copper plate 1102 may have a first surface 1104 and a second surface 1106. A conductive coating 1108, similar to conductive coating 1008, may be provided on first surface 1104 according to a pattern 1110, similar to pattern 1010. Conductive coating 1108 may be provided on second surface 1106 according to a pattern 1112, similar to pattern 1016. Note that additional features such as the groove and the recess similar to groove 908 and recess 910 as described in FIG. 9 may be provided but are not shown so as not to clutter the drawing.

During operation 1100, first surface 1104 may be etched to remove a portion of copper plate 1102 to a depth 1114. Depth 1114 is smaller than a thickness 1116 of copper plate 1102. The process may be a half-etch, as the etching is not allowed to proceed entirely through thickness 1116 of copper plate 1102. In various examples, depth 1114 may correspond to first thickness 180 as described in reference to FIG. 1F. Portions of copper plate 1102 not covered by conductive coating 1108 in first surface 1104 may be removed by the etching process, resulting in blind holes 1118 around conductive coating 1108 on first surface 1104. In some examples, an overhang 1120 may be provided along a perimeter of copper plate 1102.

As shown in FIG. 12, at operation 1200, a copper plate 1202 may be provided, similar to copper plate 1102. Copper plate 1202 may have a first surface 1204 and a second surface 1206. A conductive coating 1208, similar to conductive coating 1008, may be provided on first surface 1104 according to a pattern 1210, similar to pattern 1110. Conductive coating 1208 may be provided on second surface 1206 according to a pattern 1212, similar to pattern 1112. Note that additional features such as the groove and the recess similar to groove 908 and recess 910 as described in FIG. 9 may be provided but are not shown so as not to clutter the drawing. Blind holes 1214 may be provided around conductive coating 1208, similar to blind holes 1118 as described in reference to FIG. 11. Copper plate 1202 may include a portion 1216 corresponding to a thermal pad. During operation 1200, a semiconductor die 1218 may be attached to portion 1216 by a thermally conductive adhesive 1220. A curing process may cure thermally conductive adhesive 1220 to attach semiconductor die 1218 to copper plate 1202.

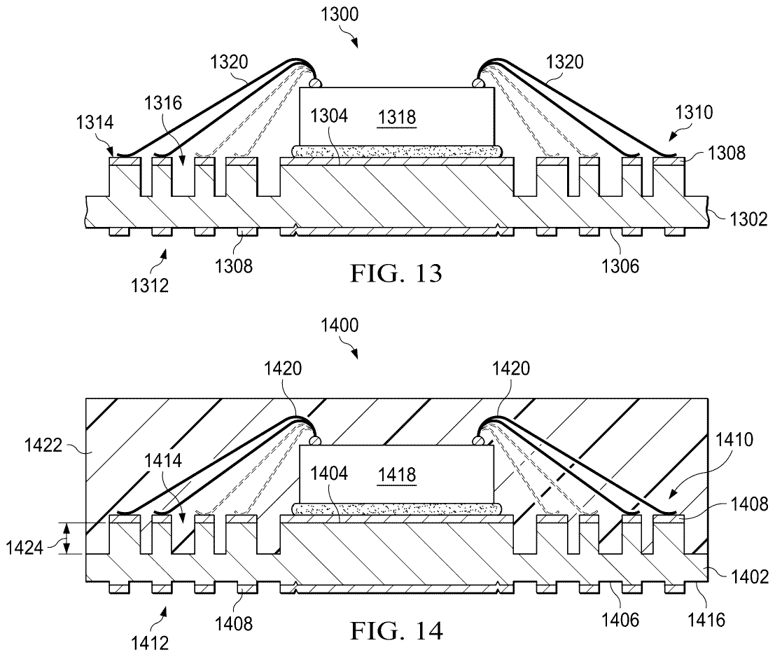

As shown in FIG. 13, at operation 1300, a copper plate 1302 may be provided, similar to copper plate 1202. Copper plate 1302 may have a first surface 1304 and a second surface 1306. A conductive coating 1308, similar to conductive coating 1008, may be provided on first surface 1304 according to a pattern 1310, similar to pattern 1210. Conductive coating 1308 may be provided on second surface 1306 according to a pattern 1312, similar to pattern 1212. Copper plate 1302 may include a portion 1314 corresponding to leads. Note that additional features such as the groove and the recess similar to groove 908 and recess 910 as described in FIG. 9 may be provided but are not shown so as not to clutter the drawing. Blind holes 1316 may be provided around portion 1314, similar to blind holes 1118 described in reference to FIG. 11. A semiconductor die 1318 may be provided, attached to copper plate 1302. During operation 1300, wires 1320 may couple semiconductor die 1318 to portion 1314 corresponding to leads with wirebonds.

As shown in FIG. 14, at operation 1400, a copper plate 1402 may be provided, similar to copper plate 1302. Copper plate 1402 may have a first surface 1404 and a second surface 1406. A conductive coating 1408, similar to conductive coating 1008, may be provided on first surface 1404 according to a pattern 1410, similar to pattern 1310. Conductive coating 1408 may be provided on second surface 1406 according to a pattern 1412, similar to pattern 1312. Note that additional features such as the groove and the recess similar to groove 908 and recess 910 as described in FIG. 9 may be provided but are not shown so as not to clutter the drawing. Blind holes 1414 may be provided around conductive coating 1408, similar to blind holes 1118 described in reference to FIG. 11. Copper plate 1402 may further include an overhang 1416, similar to overhang 1120 as described in reference to FIG. 11. A semiconductor die 1418 may be provided, attached to copper plate 1402. Wires 1420 may couple semiconductor die 1418 to copper plate 1402 with wirebonds.

During operation 1400, a mold compound 1422 may be added on first surface 1404 so as to cover semiconductor die 1418 and wires 1420 completely and subsequently cured. Before curing, mold compound 1422 may be in liquid form so as to flow into all available spaces. In various examples, mold compound 1422 may contact all surfaces of semiconductor die 1418 that are not in contact with other materials. In various examples, overhang 1416 may prevent mold compound 1422 from extending past etched depth 1424 of copper plate 1402. Mold compound 1422 may substantially fill all blind holes 1414 in copper plate 1402. In various examples, mold compound 1422 may be resistant to materials that etch copper.

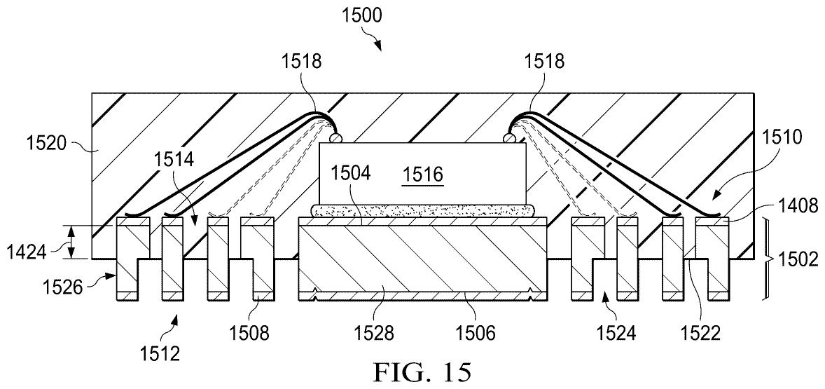

As shown in FIG. 15, at operation 1500, a copper plate 1502 may be provided, similar to copper plate 1402. Copper plate 1502 may have a first surface 1504 and a second surface 1506. A conductive coating 1508, similar to conductive coating 1008, may be provided on first surface 1504 according to a pattern 1510, similar to pattern 1410. Conductive coating 1508 may be provided on second surface 1506 according to a pattern 1512, similar to pattern 1412. Note that additional features such as the groove and the recess similar to groove 908 and recess 910 as described in FIG. 9 may be provided but are not shown so as not to clutter the drawing. Blind holes 1514 may be provided around conductive coating 1508, similar to blind holes 1118 described in reference to FIG. 11. A semiconductor die 1516 may be provided, attached to copper plate 1502. Wires 1518 may couple semiconductor die 1516 to copper plate 1502 with wirebonds. A mold compound 1520 may cover semiconductor die 1516 and wires 1518 completely and fill blind holes 1514.

During operation 1500, second surface 1506 may be etched to remove portions of copper plate 1502 that extend from a third surface 1522 of mold compound 1520 proximate to second surface 1506. This second etch process may stop at third surface 1522 as mold compound 1520 is resistant to the material used to etch copper. The etching process may result in the formation of blind holes 1524 separating leads 1526 from each other so that they are mutually electrically isolated. The etching process may also result in separation of thermal pad 1528 from leads 1526 by formation of blind holes 1524 around thermal pad 1528. Blind holes 1524 may be open at second surface 1506 and closed at third surface 1522. At the end of operation 1500, the structure of copper plate 1502 may be similar to that of leadframe 102 as described in reference to FIG. 1.

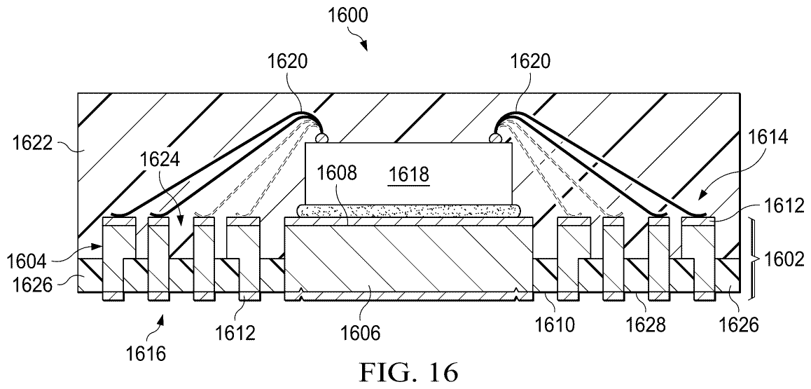

As shown in FIG. 16, at operation 1600, a leadframe 1602 may be provided, similar to copper plate 1502 at the end of operation 1500. Leadframe 1602 may comprise leads 1604 and a thermal pad 1606. Leadframe 1602 may have a first surface 1608 and a second surface 1610. A conductive coating 1612, similar to conductive coating 1008, may be provided on first surface 1608 according to a pattern 1614, similar to pattern 1510. Conductive coating 1612 may be provided on second surface 1610 according to a pattern 1616, similar to pattern 1512. Note that additional features such as the groove and the recess similar to groove 908 and recess 910 as described in FIG. 9 may be provided but are not shown so as not to clutter the drawing. A semiconductor die 1618 may be provided, attached to thermal pad 1606 of leadframe 1602. Wires 1620 may couple semiconductor die 1618 to leads 1604 of leadframe 1602. A first mold compound 1622 covers semiconductor die 1618 and wires 1620 completely, and also partially surround leads 1604. Blind holes 1624 may be provided around leads 1604 and thermal pad 1606.

During operation 1600, a second mold compound 1626 may be added around leads 1604 to fill blind holes 1624 and cured. Before curing, second mold compound 1626 may be in liquid form so as to flow into all available spaces. In some examples, the material of second mold compound 1626 may be the same as that of first mold compound 1622. In some other examples, the material of second mold compound 1626 may be different from that of first mold compound 1622. In some examples, second mold compound 1626 may be a solder resist material. The volume of second mold compound 1626 may be such that free surface 1628 of second mold compound 1626 may be recessed from second surface 1610 of leadframe 1602.

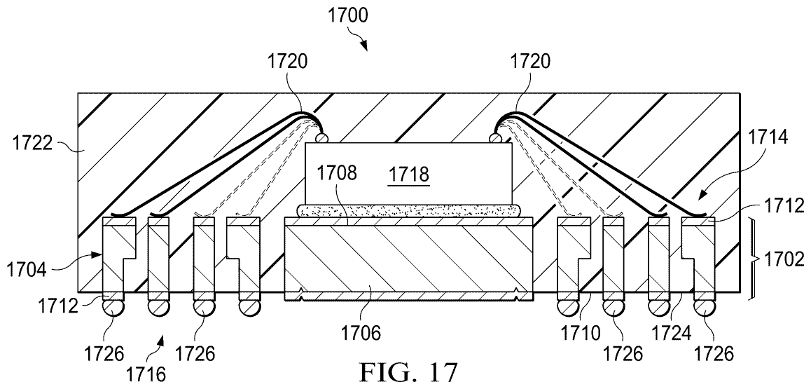

As shown in FIG. 17, at operation 1700, a leadframe 1702 may be provided, similar to leadframe 1602 at the end of operation 1600. Leadframe 1702 may comprise leads 1704 and a thermal pad 1706. Leadframe 1702 may have a first surface 1708 and a second surface 1710. A conductive coating 1712, similar to conductive coating 1008, may be provided on first surface 1708 according to a pattern 1714, similar to pattern 1614 Conductive coating 1612 may be provided on second surface 1710 according to a pattern 1716, similar to pattern 1616. Note that additional features such as the groove and the recess similar to groove 908 and recess 910 as described in FIG. 9 may be provided but are not shown so as not to clutter the drawing. A semiconductor die 1718 may be provided, attached to thermal pad 1706 of leadframe 1702. Wires 1720 may couple semiconductor die 1718 to leads 1704 of leadframe 1702. A mold compound 1722 covers semiconductor die 1718 and wires 1720 completely, and also partially surround leads 1704 and thermal pad 1706. A third surface 1724 of mold compound 1722 may be recessed with respect to second surface 1710 of leadframe 1702.

During operation 1700, solder balls 1726 may be attached to leads 1704. In some examples, a solder paste may be applied on exposed portions of leads 1704 and the structure submitted to a solder reflow process. The solder paste may form into solder balls 1726 during the operation. In other examples, individual solder balls 1726 may be picked, placed and temporarily attached (e.g., using solder paste, vibrations, etc.) in a precise operation to exposed portions of leads 1704 and subjected to the reflow operation. Any suitable process may be used to attach solder balls 1726 to leads 1704 within the broad scope of the disclosure herein. At the end of the operation, the structure may be substantially similar to the semiconductor package 100 as described in reference to FIG. 1.

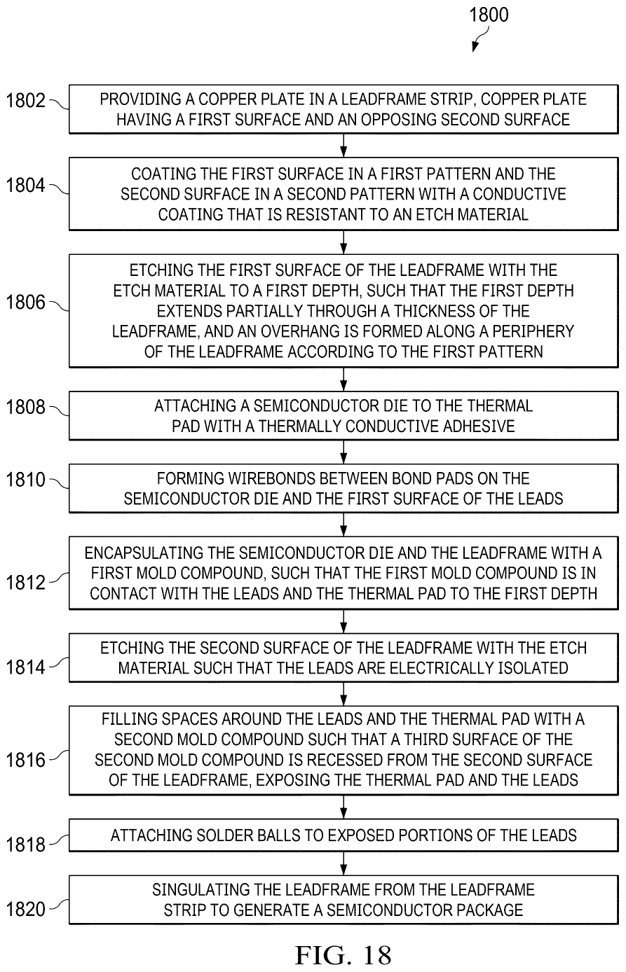

FIG. 18 is a simplified flow diagram illustrating example operations 1800 to make a thermally enhanced leadframe-based area array package similar to semiconductor package 100 as described in reference to FIG. 1. At 1802, a copper plate may be provided in a leadframe strip, the copper plate having a first surface and a second surface opposing the first surface as described in reference to FIG. 9. The copper plate may include a groove and a recess corresponding to the thermal pad features of leadframe 102 as described in reference to FIG. 9. At 1804, the first surface may be coated in a first pattern and the second surface may be coated in a second pattern with a conductive coating that is resistant to an etch material as described in reference to FIG. 10. The first pattern may correspond to the shape of leads 104 and thermal pad 110 at first surface 106 and the second pattern may correspond to the shape of leads 104 and thermal pad 110 at second surface 108 as described in reference to FIG. 1.

At 1806, the first surface may be etched with the etch material such that portions of the copper plate around the coating are removed through a partial thickness of the copper plate as described in reference to FIG. 11. In various examples, the first depth extends partially through a thickness of the leadframe, and an overhang is formed along a periphery of the leadframe according to the first pattern. At 1808, a semiconductor die is attached to the thermal pad with a thermally conductive adhesive as described in reference to FIG. 12. At 1810, wirebonds are formed between bond pads on the semiconductor die and the first surface of the leadframe as described in reference to FIG. 13. At 1812, the semiconductor die and the leadframe are encapsulated with a first mold compound, such that the first mold compound is in contact with the leads and the thermal pad to the partial thickness of the copper plate as described in reference to FIG. 14.

At 1814, the second surface of the copper plate may be etched with the etch material to form the lads and the thermal pad, such that the leads and the thermal pad are electrically isolated from each other as described in reference to FIG. 15. The etching process may result in spaces around the leads and the thermal pad. At the end of the operation, the copper plate has the structure of leadframe 102 described in reference to FIG. 1. At 1816, the spaces around the leads and the thermal pad are filled with a second mold compound, as described in reference to FIG. 16. At the end of the operation, a third surface of the second mold compound is recessed from the second surface of the copper plate/leadframe, and free surfaces of the thermal pad and the leads are not in contact with the second mold compound. At 1818, solder balls may be attached to the exposed surfaces (e.g., free surfaces) of the leads. At 1820, the leadframe may be singulated from the leadframe strip to generate a semiconductor package substantially similar to semiconductor package 100 as described in reference to FIG. 1.

Although the present disclosure has described in detail particular arrangements and configurations, these example configurations and arrangements may be changed significantly without departing from the scope of the present disclosure. For example, although the present disclosure has been described with reference to a surface mount area-array package, the same configuration and arrangements may be applicable to other types of packages, such as a pin grid area array package. Moreover, although the semiconductor package has been illustrated with reference to particular elements that facilitate the wirebonding processing functionalities on a semiconductor die attached to a leadframe, these elements and operations may be replaced by any other suitable architecture of semiconductor packages.

Although FIGS. 9-18 illustrate various operations which may be performed in a particular order, this is simply illustrative, and the operations discussed herein may be reordered and/or repeated as suitable. Further, additional operations which are not illustrated may also be performed without departing from the scope of the present disclosure. Also, various operations discussed herein with respect to FIGS. 9-18 may be modified in accordance with the present disclosure to form semiconductor package 100 as disclosed herein. Although various operations are illustrated in FIGS. 9-18 once each, the operations may be repeated as often as desired.

It is important to note that the operations described with reference to the preceding figures illustrate only some of the possible scenarios that may be implemented to fabricate the semiconductor package. Some of these operations may be deleted or removed where appropriate, or these steps may be modified or changed considerably without departing from the scope of the discussed concepts. In addition, the timing of these operations may be altered considerably and still achieve the results taught in this disclosure. The preceding operational flows have been offered for purposes of example and discussion.

The above description of illustrated implementations of the disclosure, including what is described in the abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

1. A semiconductor package, comprising:
a semiconductor die attached to a thermal pad and connected to a lead, the lead including a first surface and a second surface opposing the first surface, and the thermal pad including a third surface and a fourth surface opposing the third surface;
a wire coupled to the semiconductor die and the first surface of the lead;
a solder ball coupled to the second surface of the lead; and
mold compound in contact with the lead, the thermal pad, and the semiconductor die, wherein:
a fifth surface of the mold compound is recessed with respect to the second surface of the lead and the fourth surface of the thermal pad, and
a first portion of the solder ball and a second portion of the thermal pad are not in contact with the mold compound.

2. The semiconductor package of claim 1, further comprising a plurality of leads arranged in an area array around the thermal pad, wherein:
at least two adjacent leads in the plurality of leads are of different lengths, and
the at least two adjacent leads are oblique with respect to sides of the semiconductor package.

3. The semiconductor package of claim 2, further comprising a plurality of wires and a plurality of solder balls, wherein each lead is coupled to a respective wire on the first surface and a respective solder ball on the second surface.

4. The semiconductor package of claim 1, wherein the mold compound does not contact a portion of the second surface of the lead.

5. The semiconductor package of claim 1, wherein:
the thermal pad includes a groove proximate to a periphery of the thermal pad,
the mold compound does not extend beyond the groove towards a center of the thermal pad, and
a portion of the mold compound is between the groove and a periphery of the thermal pad.

6. The semiconductor package of claim 1, wherein:
the lead comprises a first conductive material,
the first surface, the second surface, the third surface and the fourth surface comprise respective coatings of a second conductive material, and
the first conductive material is different from the second conductive material.

7. The semiconductor package of claim 1, wherein:
the lead comprises a first portion having a first thickness and a second portion having a second thickness,
the first thickness is less than the second thickness, and
the solder ball is coupled to the second portion.

8. A semiconductor package, comprising:
a semiconductor die coupled to a first surface of a thermal pad;
a plurality of leads arranged in an area array around the thermal pad, wherein:
the area array comprises rows and columns of leads between the thermal pad and any side of the semiconductor package, and
any row or any column includes at least two leads;
wires coupled to the semiconductor die and the leads; and
a mold compound in contact with the leads, the thermal pad, and the semiconductor die, wherein a third surface of the mold compound is recessed with respect to a second surface of the thermal pad opposite to the first surface.

9. The semiconductor package of claim 8, wherein the leads are coupled to solder balls capable of being attached to a printed circuit board.

10. The semiconductor package of claim 9, wherein the thermal pad in the semiconductor package is thermally coupled to a heat sink.

11. The semiconductor package of claim 8 wherein:
the mold compound comprises a first material and a second material, wherein the second material is different from the first material,
the first material extends partially along a thickness of the thermal pad between the first surface and the second surface, and
the second material extends between the first material and the third surface of the mold compound.

12. The semiconductor package of claim 11, wherein the second material comprises a solder resist material.

13. The semiconductor package of claim 8, wherein:
at least two adjacent leads in a row are of different lengths, and
the leads are oblique with respect to the thermal pad.

14. The semiconductor package of claim 8, wherein the first surface and the second surface are coated with a material comprising nickel, palladium and gold.

15. A semiconductor package, comprising:
a semiconductor die on a thermal pad;
a plurality of leads arranged in an area array around the thermal pad, wherein:
the area array comprises rows and columns of leads between the thermal pad and any side of the semiconductor package,
any row or any column includes more than one lead,
adjacent leads in any one row are of different lengths, and
the leads are oblique with respect to sides of the semiconductor package;
solder balls coupled to the leads; and
a mold compound in contact with the leads, the thermal pad, and the semiconductor die.

16. The semiconductor package of claim 15, further comprising wires coupled with the semiconductor die and the leads.

17. The semiconductor package of claim 15, wherein:
the thermal pad has a first surface and a second surface,
the semiconductor die is on the first surface; and
a third surface of the mold compound is recessed with respect to the second surface of the thermal pad.

18. The semiconductor package of claim 15, wherein the mold compound comprises a first layer and a second layer of different materials, the first layer being in contact with the semiconductor die.

19. The semiconductor package of claim 18, wherein the second layer comprises solder resist.

20. The semiconductor package of claim 15, further comprising a heat sink coupled to the thermal pad opposite to the semiconductor die.
